(19) United States
(12) Patent Application Publication
(10) Pub. No.: US 2013/0269173 A1
(43) Pub. Date: Oct. 17, 2013

(54) APPARATUS AND METHOD FOR AUTOMATED SORT PROBE ASSEMBLY AND REPAIR

(71) Applicants: Todd P. Albertson, Warren, OR (US); David M. Craig, Hillsboro, OR (US); Anil Kaza, Hillsboro, OR (US); David Shia, Hillsboro, OR (US)

(72) Inventors: Todd P. Albertson, Warren, OR (US); David M. Craig, Hillsboro, OR (US); Anil Kaza, Hillsboro, OR (US); David Shia, Hillsboro, OR (US)

(21) Appl. No.: 13/995,931

(22) PCT Filed: Dec. 30, 2011
(86) PCT No.: PCT/US11/68229

§ 371 Date: Jun. 19, 2013

(51) Int. Cl. G01R 3/00

(52) U.S. Cl. CPC G01R 3/00; Y10S 901/02
USPC 29/593; 29/729; 29/705; 29/592.1; 901/2

(57) ABSTRACT

An apparatus comprising a robot; an end effector coupled to the robot and configured to grasp or transfer a probe of a size for use in a probe card; and instructions stored on a machine readable medium coupled to the robot, the instructions comprising to configure the robot to transfer a probe to a probe card substrate or, where the probe is attached to a probe card substrate, to move the probe. A method comprising automatically transferring a probe to a probe card substrate in an assembly process or, where the probe is attached to a probe card substrate, moving the probe in a repair process; and after transferring or moving the probe, heating the probe with a heat source.

### BACKGROUND

1. Field

Sort probe assembly and repair.

2. Description of Related Art

In the manufacture of semiconductor devices, it is necessary that such devices be tested at the wafer level to evaluate their functionality. The process in which die in a wafer are tested is commonly referred to as “wafer sort.” Testing and determining design flaws at the die level offers several advantages. First, it allows designers to evaluate the functionality of new devices during development. Increasing packaging costs also make wafer sorting a viable cost saver, in that reliability of each die on a wafer may be tested before incurring the higher costs of packaging. Measuring reliability also allows the performance of the production process to be evaluated and production consistency rated, such as for example by “bin switching” whereby the performance of a wafer is downgraded because that wafer's performance did not meet the expected criteria.

Generally, two tests are conducted on devices at the wafer level. The first test is conducted to determine if any of the individual devices on the wafer are functional. A second test is conducted to determine a performance parameter for the good devices on the wafer. For example, currently wafers have hundreds to thousands of microprocessors. Each of these microprocessors is tested to determine if the microprocessor is good. The speed of the microprocessor is determined in a second test. Once measured, the speed of the microprocessor is saved and the location of the microprocessor on the wafer is noted. This information is used to sort the microprocessors based on performance at the time the wafer is sliced and diced to form individual dies, each of which has a microprocessor thereon.

Each device formed on a wafer has a number of electrical contacts. For example, testing an individual microprocessor commonly requires hundreds to thousands of different individual contacts to be made to the microprocessor on the wafer. Testing each contact requires more than merely touching each electrical contact. An amount of force must be applied to a contact to break through any oxide layer that may have been formed on the surface of the contact. Forming 3000 contacts which are not all at the same height and not all in the same plane is also difficult. As a result, a force has to be applied to the contacts to assure good electrical contact and to compensate for the lack of planarity among the contacts.

A membrane probe card is currently used to conduct high frequency sort and test procedures. The membrane probe card includes a rigid substrate and a large number of electrical probes. Probe card substrates have for example 500 to 7,000 probes or more depending, for example, on the microprocessor testing requirements. The probes include an attached end and a free end to contact individual electrical contacts on a device. Repair of a probe card substrate, such as when a probe is deformed (e.g., recessed) is generally work that has to be done by hand. Similarly, assembly of probes on/in a probe card substrate is time consuming work that generally involves placing probes on the probe card substrate by hand.

### BRIEF DESCRIPTION OF THE DRAWINGS

FIG. 1 shows a schematic side view representation of an embodiment of a system suitable to repair or assemble a probe card substrate;

FIG. 2 shows a top view of a portion of the system of FIG. 1;

FIG. 3 is a flow chart of an embodiment of a process for repairing a probe card substrate;

FIG. 4 is graphical representation of possible temperature profiles to apply to a probe;

FIG. 5 is a flow chart of an embodiment of a process for assembling a probe card substrate;

FIG. 6 is a side view of a portion of space transformer substrate having solder and paste on a surface;

FIG. 7 shows the substrate of FIG. 6 and the attachment of probes to the substrate;

FIG. 8 shows a schematic side view representation of a second embodiment of a system suitable to repair or assemble a probe card substrate;

FIG. 9 shows a top view of a portion of the system of FIG. 8.

### DETAILED DESCRIPTION

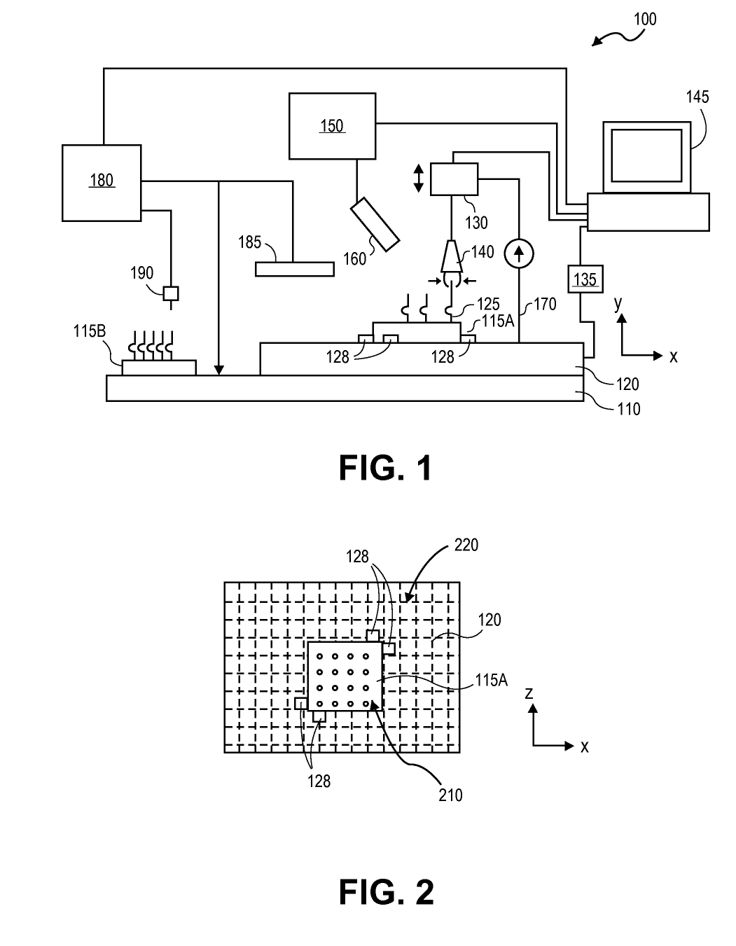

FIG. 1 shows one embodiment of a system that may be used for the automated repair of a probe card substrate such as a space transformer of a probe card and/or an assembly of a probe card substrate. System 100 includes platform 110 onto which substrate 120 is mounted. Substrate 120, in one embodiment, has a surface area that can accommodate a probe head or a full probe card. In this embodiment, substrate 120 is a substrate that is translatable in an x- and a z-direction. Representatively, substrate 120 is translatable in x and y directions according to a grid system configurable for the pitch of a probe card substrate. A representative pitch is on the order of 40 microns (μm) to 130 μm. It is appreciated that other pitches may be utilized. FIG. 2 shows a top view of substrate 120 and illustrates the xz-pitch 220 in a grid of dashed lines. Control of the translation of substrate 120 is provided by machine-readable instructions in processor 145 to which substrate 120 is connected through motor 135. In one embodiment, placement of a probe card substrate, such as probe card substrate 115A, on substrate 120 is controlled so that its location and x- and z-coordinates are known by processor 145. One way the placement of a probe card substrate on substrate 120 is known is by alignment blocks 128 on substrate 120.

Referring again to FIG. 1, also connected to processor 145 is robot 130. The term robot is to be interpreted broadly as a conveyance, transfer device, electro-mechanical transfer device or mechanism, or automatically controlled, reprogrammable, multipurpose manipulator programmable in three, four, or more axes. Robot 130 may take various forms or configurations, consistent with its intended purpose. For example, in various embodiments, robot 130 may be a Gantry or Cartesian coordinate type robot, a selective compliant assembly robot arm (SCARA) type robot, an articulated arm type robot, or a combination thereof (e.g., a SCARA type robot coupled in a Gantry type robot configuration).

In one or more embodiments, robot 130 may have a robotic arm or other mechanical limb. The arm or limb may include an interconnected set of two or more links and one or more powered joints. In one or more embodiments, the arm or limb may allow rotation or movement in at least four axes. As is known, the flexibility or freedom of movement of the arm increases with increasing number of axes. The arm or limb may support and move an end-of-arm tooling or other end effector that is connected at the end of the arm or limb.

The end effector may allow the robot to perform certain intended functions, such as, for example, engaging with an item (e.g., a probe), holding and moving the item, and disengaging from the item. In one or more embodiments, the end effector may include gripper 140. Gripper 140 may serve as a “hand” to grasp, clasp, or otherwise engage with, hold and move, and disengage from an item. As one example, gripper 140 may include two opposed jaws, claws, or fingers coupled at a joint, or a pincer-like mechanism, which is able to open and close. An actuatable sleeve may be placed proximal to the jaws, claws or fingers. The actuatable sleeve may be attached to, for example, a linear motor, that can be translated distally toward and/or over the jaws, claws or fingers once the jaws, claws or fingers have grasped a probe to establish a firm (controlled) grip on the probe.

Robot 130 may be programmed with an application program, program routine, or other set of machine-readable instructions in processor 145. The program or set of instructions may specify one or more operations the robot is to autonomously or at least semi-autonomously perform. Representatively, the program or set of instructions may specify the movements (e.g., coordinates, distances, directions, etc.), end effector actions, timing or triggers, and like information associated with the operations.

In one embodiment, robot 130 is configured to move in a work envelope. That work envelope includes movement in a y-direction (e.g., up or down as viewed) and may include an x-direction and/or z-direction in an area above substrate 120 or beyond substrate (e.g., including an area adjacent substrate 120 where probes are stored). Gripper 140 representatively includes tongs for grasping a probe. Such probe may have a square or round diameter and is representatively one-half the pitch. Therefore, the tongs of gripper 140 are configured to be able to grasp a probe that is representatively one-half the pitch that has a diameter one-half the pitch. For a 130 μm pitch probe card, a representative diameter is on the order of 65 μm. One suitable gripper is a gripper commercially available from FemtoToold GmbH of Switzerland.

In a repair process, robot 130 is configured to move in a y-direction to grasp a probe on a probe card substrate such as probe card substrate 115A. Control of robot 130 is provided by instructions in processor 145. Such instructions include instructions for lowering robot 130 such that gripper 140 is aligned with the probe and its tongs may grasp a probe; instructions for grasping a probe; and instructions for moving the probe. In an embodiment where system 100 is configured for a probe card assembly process, robot 130 may also be configured to move in a second direction (e.g., x- or z-direction) to retrieve a probe and bring the retrieved probe to a probe card substrate, such as probe card substrate 115 and substrate 120. Robot 130, in one embodiment, has an integrated motor to allow the translation in a y-direction and optionally in a second direction (x- or z-direction).

System 100 in FIG. 1, in one embodiment, also includes a heat source to heat a probe, for example, while the probe is grasped by gripper 140. Heating of a probe may be desired, for example, to repair a configuration of a probe that is connected to a probe card substrate or to affix a probe to a probe card substrate. FIG. 1 shows heat source 170 that is representatively a resistive heat source. A resistive heat source provides a current to robot 130 and the tongs of gripper 140. Such current introduces heat into a probe, such as probe 125 on substrate 115A. It is appreciated that other heat sources are also suitable. Representatively, the heat source may be provided by a laser that directs light energy at a grasped probe such as probe 125. A third way of heating a grasped probe is to enclose substrate 120 in an enclosure such as an oven that may be heated.

System 100 of FIG. 1 also includes vision module 150. Vision module 150 includes imaging submodule 150 that has a field of view including probe card substrate 115A, one or more probes on substrate 115A and a portion of gripper 140 including the entire portion. Vision module 150 also includes a reproduction submodule connected to the imaging submodule to reproduce the field of view of the submodule on a screen, such as screen associated with processor 145. Vision module 150 permits optical metrology testing of probes and allows an operator to view the repair or assembling of the probe card substrate, such as probe card substrate 115A, and may also be used to identify a location on a probe card substrate for assembly or repair using positioning instructions.

In the embodiment illustrated in FIG. 1, system 100 also includes testing module 180. Testing module 180 is connected to processor 145 and, in one embodiment, is in a second area of platform 110 away from substrate 120. FIG. 1 shows probe card substrate 115B that is, for example, an assembled or repaired probe card substrate on platform 110 that may be undergoing testing by testing module 180. Testing module 180 is configured to test a probe that is connected to a probe card substrate or a series of probes connected to the probe card substrate. In one embodiment, testing module 180 includes conductor plate 185 for planarity measurements. Representatively, testing module 180 also includes submodule 190 that may be used, representatively, to test the continuity of individual probes and for spring constant measuring.

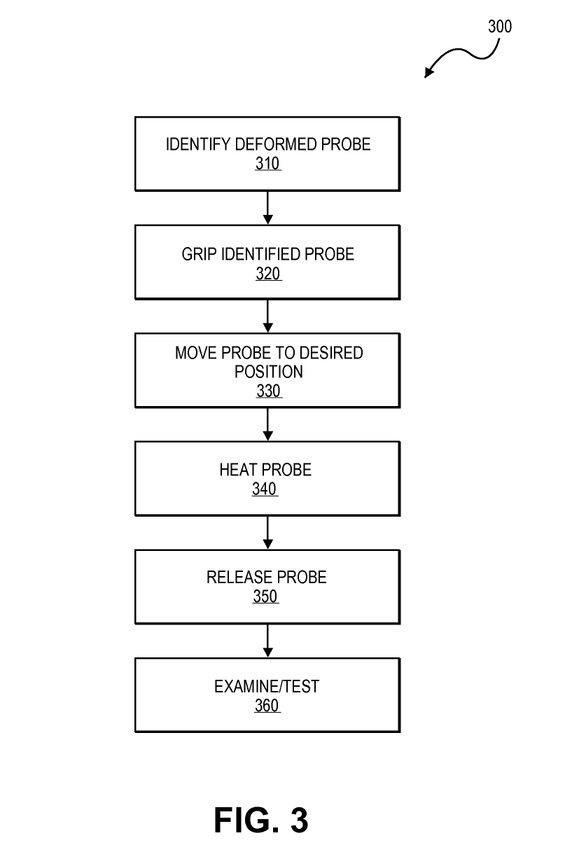

In wafer sort, where devices are tested by a probe card substrate at the wafer level, probes of a probe card substrate are brought in to contact with contact points of a device. It is not uncommon during “touch down” on a wafer, that high currents are experienced on a probe. Such high currents can increase the temperature of a probe to a point where the probe deforms, such as to recesses. Accordingly, in one embodiment, it is desired to repair probes on a probe card substrate that have been deformed such as, for example, by high currents during touch down. The system described with respect to FIG. 1, provides one system for repair of probes on a probe card substrate. FIG. 3 shows a flow chart of one process to repair a probe on a probe card substrate that might be used in conjunction with system 100 of FIG. 1. Referring to FIG. 3, initially, a deformed probe must be identified (block 310). Such identification can be done by a visual examination or by vision module 150 of system 100. Representatively, imaging submodule 160 may scan probe card substrate 115A to view probe 125 on a substrate. Processor 145 contains a coordinate system (e.g., a positioning system) to identify a location of the deformed probe. Once identified, substrate 120 is moved in an x- and/or z-direction to position gripper 140 of robot 130 over a deformed probe. In another embodiment, where, for example, robot 130 may be translated in an x-direction and a z-direction, processor 145 directs the movement of robot 130 to a location of the deformed probe. To overcome any inaccuracies in the positioning of robot 130, processor 145 then directs the movement of substrate 120 to precisely position gripper 140 over a deformed probe.

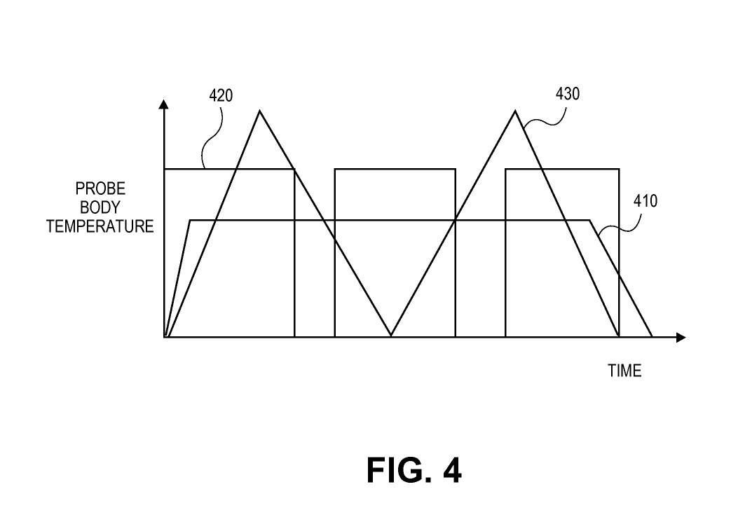

Once gripper 140 of robot 130 is positioned over the deformed probe, processor 145 instructs robot 130 to translate in a y-direction towards probe card substrate 115A over the deformed probe and to grasp the deformed probe (block 320). Robot 130 then moves a probe to a desired position (block 330). Where the probe has been recessed, such movement may be to unrecess or to pull a probe to a desired position. Once the probe is in a desired position, processor 145 directs the heating of the probe (block 340). As noted above, in one embodiment, resistive heat is provided through robot 130 and gripper 140 to the probe. The probe is heated for a predetermined time to assist in the fixation of the desired position. Representatively, a predetermined time is on the order of 10 seconds to several minutes. FIG. 4 shows representative temperature profile for heating a probe body. Representative profiles include heating and maintaining a probe at a constant temperature for a period of time 410, square pulse heating of a probe body 420 and triangular heating of a probe 440. Following heating, the probe is allowed to cool to room temperature and released (block 350) and robot 130 returned to a position away from probe card substrate 115A. Following the release of the probe, probe card substrate 115A may be visualized to identify any other deformed probes. The process may be repeated on the probe if the repair is unsatisfactory. Having been satisfied that there are no other deformed probes that may be incurred, the probe card substrate is examined and tested in, for example, testing module 180 (block 360).

In the above embodiment, gripper 140 was translated in a y-direction to grasp the probe and then to move the probe. In another embodiment, gripper 140 is fixed in a y-direction (i.e., cannot be translated in a y-direction). In such an embodiment, substrate 120 is translated (e.g., up to make contact with gripper 140 and down to move the probe (to unrecess the probe).

In a situation where a probe cannot be repaired, in another embodiment, the probe can be grasped by gripper 140 and removed, for example, by breaking it off. Heat from heat source 170 may be supplied to assist in the removal. Such a repair is suitable for probe card substrates that have a sufficient number of probes to carry out a function without the removed probe.

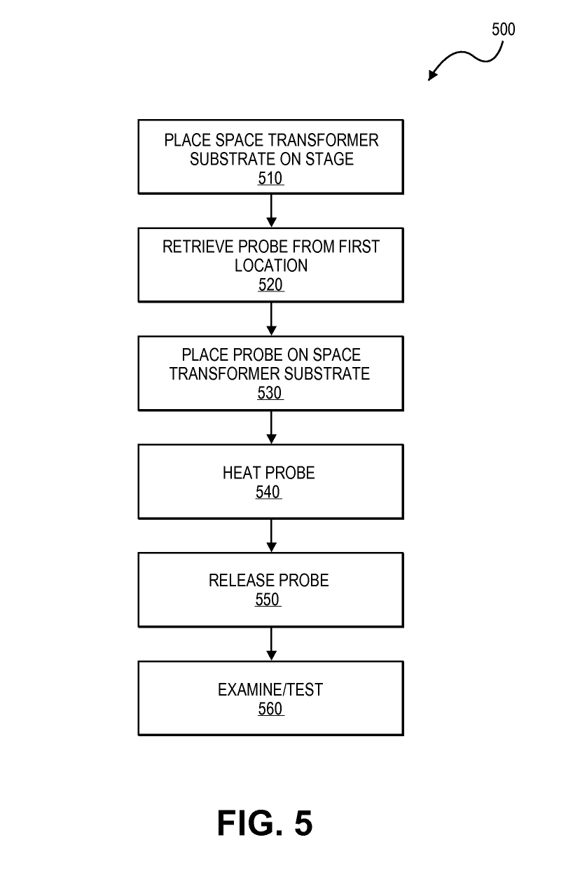

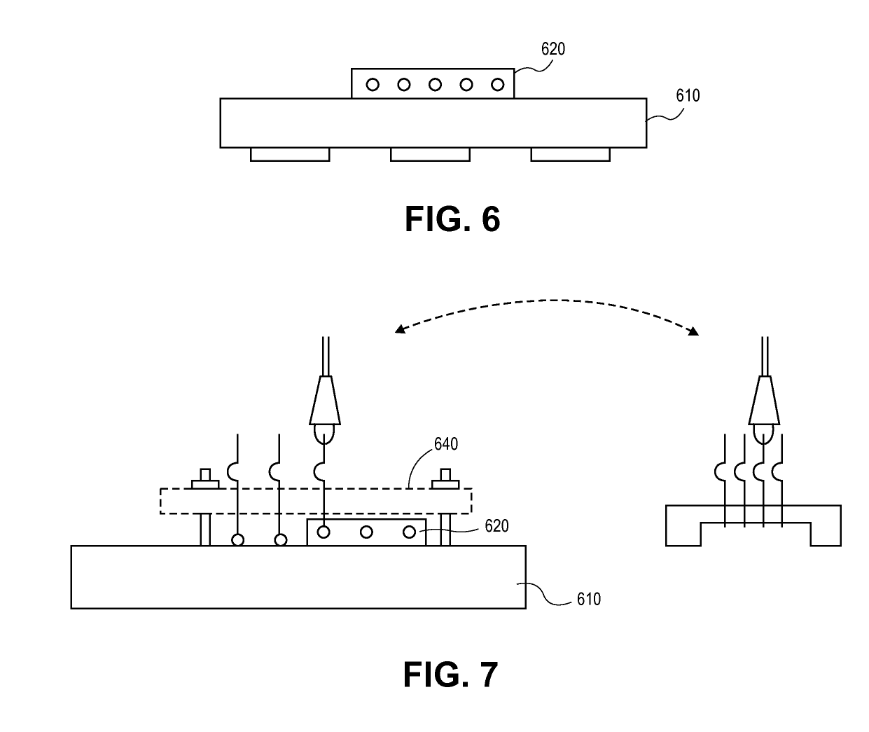

FIG. 5 shows a flowchart of one process for assembly of a probe card substrate such as probe card substrate 115A in FIG. 1. Assembly in one sense is the placement and attachment of probes into or on the substrate. In one embodiment, a probe card substrate is a space transformer. To prepare the space transformer for attachment of probes, a surface of the space transformer is printed with solder and paste. FIG. 6 shows a side view of a space transformer. Space transformer 610 has a surface onto which probes will be attached. Overlying the surface of space transformer 610 in an area designated for probe attachment is printed solder and paste 620. Once the solder and paste is printed onto the surface of the space transformer, the space transformer is placed on a stage, such as stage 120 of FIG. 1 (block 510 of FIG. 5). Processor 145 will direct movements of robot 130 to retrieve a probe from a first location and to bring the probe to an area above the stage (block 520, FIG. 5). Representatively, the probe will retrieve the probe from a first location by using gripper 140 and move the grasped probe to an area over the probe card substrate (over probe card substrate 115A in FIG. 1). In one embodiment, to overcome any inaccuracies in the positioning of robot 130, processor 145 then directs the movement of substrate 120 to precisely align the grasped probe with a desired area over the space transformer. Processor 145 will then direct robot 130 to place the probe on the space transformer in a desired area (block 530). Robot 130, once positioned, will translate gripper 140 in a y-direction (e.g., downward) to contact the probe with the solder and paste on a surface of the space transformer. In one embodiment (depicted on the left side of the flow chart in FIG. 5), while the probe is grasped by the gripper, the probe is heated by heat source 170 to solder the probe in place on the space transformer (block 540, FIG. 5). Once the probe is soldered in place, the gripper will release the probe. Processor 145 then determines whether another probe needs to be retrieved and placed on the space transformer (block 555). If another probe is needed, robot 130 may be directed by processor 145 to retrieve another probe. The robot with another grasped probe is then moved to an area over the space transformer with possible additional movement of substrate 120 to precisely align the grasped probe with a desired area. The probe is placed and heated and the process of picking, placing and heating probes is continued until the desired number of probes are attached to the space transformer. Once the desired number of probes are placed on the space transformer, the space transformer may be examined and tested, for example, in testing module 180 (block 560).

In another embodiment (depicted on the right side of the flow chart in FIG. 5), once the probe is contacted with the solder and paste, the probe is released by the gripper and the point of contact is examined (block 565). Processor 145 then determines whether another probe needs to be retrieved and placed (block 565). If another probe is needed, robot 130 may be directed by processor 145 to retrieve another probe. The robot with another grasped probe is then moved to an area over the space transformer (over probe card substrate 115A in FIG. 1) with possible additional movement of substrate 120 to precisely align the grasped probe with a desired area. The process of picking, placing and examining probes is continued until the desired number of probes are placed on the space transformer. Once the desired number of probes are placed on the space transformer, the space transformer is heated to collectively attach all the probes to the space transformer (block 580) with the solder. One way this may be done is by placing the space transformer in an oven or carrying out the pick and place process in a chamber that can be heated to a temperature to melt the solder. Once the probes are attached, the space transformer may be examined and tested (block 590).

FIG. 7 shows the pick and place process on space transformer 610 of FIG. 6. FIG. 7 shows that probes may be soldered individually without support. Alternatively, the probes may be supported by optional support plate 640 that adds structural support to the final assembly. The structural support plate 640 may be removed once all the probes have been attached to substrate 610.

The grasping of deformed probes by a robot/gripper described with reference to FIG. 3 and the pick and place process of assembling probes on a probe card substrate described with reference to FIG. 5 are improvements over manual techniques. The automated process reduces the lead time in assembling a probe card substrate, improves the yield and reduces costs. The robot and end effector (gripper) eliminates the need for human interaction with a probe or placement of the probe. Instead, the robot can be controlled by a processor to grasp and move probes precisely to respective desired locations. Furthermore, by making use of a system that can pass heat to a probe, a robot/gripper does not require significant displacement to push and/or pull a probe to a desired position in a repair process which reduces damage and improves the attachment process in an assembly process.

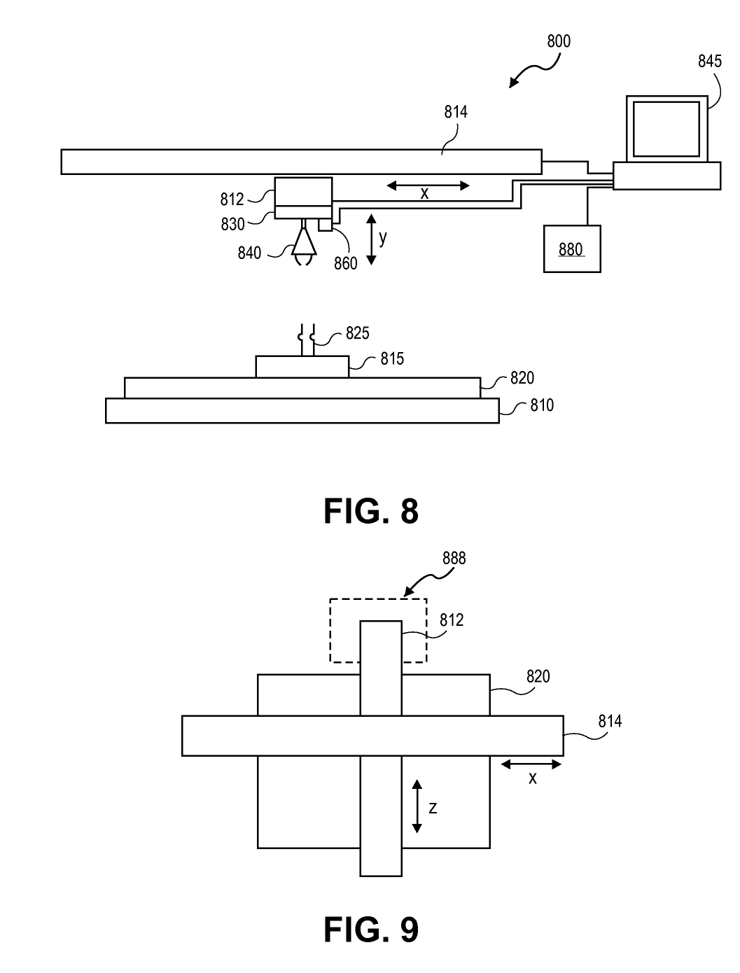

In the embodiment described above with respect to system 100 and its operation, the system relied on a translatable stage that is translatable and gives direction. The translatable stage permitted the alignment of a substrate such as a probe card substrate with a robot for the placement of probes on a substrate. FIG. 8 shows another embodiment of a system. System 800 includes platform 810 onto which substrate 820 is mounted. Substrate 820, in one embodiment, is stationary and in another embodiment, is translatable in an x- and a z-direction similar to substrate 120 in FIG. 1 by instructions provided by processor 845.

Referring again to FIG. 8, also connected to processor 845 is robot 830. As described above, robot 830 may take various forms or configurations, consistent with its intended purpose. Connected to robot 830 is an end effector such as gripper 840. Robot 830 is configured to move in a work envelope. That work envelope includes movement in a y-direction (e.g., up or down as viewed). In this embodiment, robot is connected to first track 812 that extends in a z-direction at least the length of substrate 820. The z-position of track 812 is fixed to define a z-direction work envelope of robot 130. Track 812 is translatably connected to track 814 by, for example rails. Track 814 extends in an x-direction with the x-position of track 814 fixed to define an x-direction work envelope of robot 830. FIG. 9 shows a top view of substrate 820 and illustrates track 812 and track 814. Control of the translation of track 812 and robot 830 is provided by machine-readable instructions in processor 845 to which track 812 and robot 830 are connected through a motor. FIG. 9 also shows track 812 extends to area 888 that is, for example, an area where stored probes may be located.

Other features of system 800 are similar to that of system 100 in FIG. 1. Those features include vision module 860 connected to robot 830 and testing module 880.

In the above embodiments for assembling a probe card substrate, a pick and place process was described where a robot picked up a probe and placed the probe on a probe card substrate (e.g., on a space transformer). In another embodiment, a robot may include a magazine having storage capacity for a number of probes (e.g., hundreds of probes, thousands of probes) and dispensing capability. Referring to FIG. 1, robot 130 may include a magazine with a number of probes therein. Instead of a gripper, in this embodiment, the end effector of robot 130 includes a barrel. Robot 130 would then be aligned over an area of probe card substrate 115A where it is desired to place a probe and, once aligned, a probe may be dispensed from the magazine through the barrel and onto the substate. In another embodiment, rather than having a magazine with preformed probes, the magazine associated with robot 130 contains a spool of probe material (e.g., metal wire) and dispensing capability. In this embodiment, the end effector of robot 130 may include a barrel as well as a cutting mechanism (e.g., actuatable snips within the barrel). In operation, robot 130 would be aligned over an area of probe card substrate 115A where it is desired to place a probe and, once aligned, processor 145 directs that a length of probe material be dispensed through the barrel of robot 130 onto the probe card substrate. Once a desired length is dispensed and attached to the probe card substrate, the length is cut from the spool of probe material to form a probe.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

1. An apparatus comprising:
a robot;
an end effector coupled to the robot and configured to grasp or transfer a probe of a size for use in a probe card substrate; and
instructions stored on a machine readable medium coupled to the robot, the instructions comprising to configure the robot to transfer a probe to a probe card substrate or, where the probe is attached to a probe card substrate, to move the probe.

2. The apparatus of claim 1, further comprising a heat source and the instructions further comprise instructions to heat a grasped probe with the heat source.

3. The apparatus of claim 1, wherein the instructions to move a probe comprise instructions to move a grasped probe from a first position to a second position and the instructions to heat a grasped probe to a predetermined temperature for a predetermined time.

4. The apparatus of claim 1, wherein the instructions to transfer a probe to a probe card substrate further comprise instructions to move the probe card substrate to a predetermined position to provide a location for the transfer of the probe.

5. The apparatus of claim 1, wherein the robot comprises a work envelope and the end effector comprises gripper and the instructions to transfer a probe to a probe card substrate further comprise instructions to move the gripper to a first location in the work envelope to grasp a probe and to move to a second location within the work envelope to transfer the grasped probe.

6. The apparatus of claim 5, wherein the second location within the window is configured to contain a probe card substrate, and the instructions further comprise instructions to place a grasped probe onto the probe card substrate at a location.

7. The apparatus of claim 6, further comprising a heat source and the instructions further comprise instructions to heat a grasped probe with the heat source.

8. The apparatus of claim 1, wherein the robot is capable of movement in at least two axes.

9. An apparatus comprising:
a robot comprising a work envelope;
an end effector coupled to the robot and configured to grasp a probe of a size for use in a probe card substrate;
a substrate base defining a first location within the work envelope;
a heat source; and
instructions stored on a machine readable medium coupled to the robot, the instructions comprising:
to configure the robot to transfer a probe to a probe card substrate on the substrate base in an assembly process or, where the probe is attached to a probe card substrate, to configure the robot to move the probe in a repair process, and
to heat the probe with the heat source.

10. The apparatus of claim 9, further comprising a vision module comprising an imaging submodule comprising a field of view and a reproduction submodule coupled to the imaging submodule to reproduce the field of view of the imaging submodule on a screen for display.

11. The apparatus of claim 9, further comprising a testing module configured to test a probe coupled to a probe card substrate.

12. The apparatus of claim 9, wherein the instructions to transfer a probe to a probe card substrate further comprise instructions to move a probe card substrate on the substrate base to a predetermined position to receive the transfer of the grasped probe.

13. The apparatus of claim 9, wherein the end effector comprises a gripper instructions to transfer a probe to a substrate further comprise instructions to move the gripper to a second location in the work envelope to grasp a probe and to move to the first location within the work envelope to transfer the grasped probe.

14. The apparatus of claim 13, wherein the instructions further comprise instructions to place a grasped probe onto the substrate at a location within the substrate.

15. A method comprising:
automatically transferring a probe to a probe card substrate in an assembly process or, where the probe is attached to a probe card substrate, moving the probe in a repair process; and
after transferring or moving the probe, heating the probe with a heat source.

16. The method of claim 15, wherein transferring or moving the probe comprises moving the substrate.

17. The method of claim 15, wherein after transferring the probe, coupling the probe to the substrate.

18. The method of claim 15, wherein heating the probe, the method further comprises testing the probe.
